(19) United States
(12) Patent Application Publication
(10) Pub. No.: US 2010/0006812 A1
(43) Pub. Date: Jan. 14, 2010

(54) CARBON-BASED RESISTIVITY-SWITCHING MATERIALS AND METHODS OF FORMING THE SAME

(75) Inventors: Huiwen Xu, Sunnyvale, CA (US); Xiying Chen, San Jose, CA (US); Roy E. Scheuerlein, Cupertino, CA (US); Er-Xuan Ping, Fremont, CA (US); Tanmay Kumar, Pleasanton, CA (US); Alper Ilkbahar, San Jose, CA (US)

Correspondence Address: DUGAN & DUGAN, PC, 245 Saw Mill River Road, Suite 309, Hawthorne, NY, 10532, US

(73) Assignee: SanDisk 3D LLC, Milpitas, CA (US)

(21) Appl. No.: 12/499,467

(22) Filed: Jul. 8, 2009

Related U.S. Application Data
(60) Provisional application No. 61/078,924, filed on Jul. 8, 2008.

(51) Int. Cl. H01L 29/02; H01L 21/00

(52) U.S. Cl. 257/2; 438/485; 977/773; 257/E29.006; 257/E21.001

(57) ABSTRACT

Memory devices including a carbon-based resistivity-switchable material, and methods of forming such memory devices are provided, the methods including introducing a processing gas into a processing chamber, wherein the processing gas includes a hydrocarbon compound and a carrier gas, and generating a plasma of the processing gas to deposit a layer of the carbon-based switchable material on a substrate within the processing chamber. Numerous additional aspects are provided.

### CROSS REFERENCE TO RELATED APPLICATIONS

The present application claims the benefit of U.S. Provisional Patent Application Ser. No. 61/078,924, filed Jul. 8, 2008, and titled “Carbon-Based Resistivity-Switching Materials And Methods Of Forming The Same” (Docket No. MXA-294P), which hereby is incorporated by reference herein in its entirety for all purposes.

The present application is related to U.S. patent application Ser. No. 12/421,405, filed Apr. 9, 2009, and titled “Damascene Integration Methods For Graphitic Films In Three-Dimensional Memories And Memories Formed Therefrom” (“the '405 application”) (Docket No. MXD-247), which hereby is incorporated by reference herein in its entirety for all purposes.

The present application also is related to U.S. Provisional patent application Ser. No. 12/465,315, filed May 13, 2009, and titled “Carbon-Based Interface Layer For A Memory Device And Methods Of Forming The Same” (“the '315 application”) (Docket No. MXA-293), which hereby is incorporated by reference herein in its entirety for all purposes.

The present application further is related to U.S. Provisional Patent Application Ser. No. 61/082,180, filed Jul. 18, 2008, and titled “Carbon-Based Resistivity-Switching Materials And Methods Of Forming The Same” (“the '180 application”) (Docket No. MXA-325P), which hereby is incorporated by reference herein in its entirety for all purposes.

### TECHNICAL FIELD

The present invention relates to microelectronic structures, such as non-volatile memories, and more particularly to carbon-based resistivity-switching materials, such as for use in such memories, and methods of forming the same.

### BACKGROUND

Non-volatile memories formed from reversible resistance-switchable elements are known. For example, U.S. patent application Ser. No. 11/125,939, filed May 9, 2005, and titled “Rewriteable Memory Cell Comprising A Diode And A Resistance-Switching Material”, which is hereby incorporated by reference herein in its entirety for all purposes, describes a three-dimensional, rewriteable non-volatile memory cell that includes a diode coupled in series with a reversible resistivity-switchable material such as a metal oxide or metal nitride.

It is also known that certain carbon-based films may exhibit reversible resistivity-switching properties, making such films candidates for integration within a three-dimensional memory array. For example, U.S. patent application Ser. No. 11/968,154, filed Dec. 31, 2007, titled “Memory Cell That Employs A Selectively Fabricated Carbon Nano-Tube Reversible Resistance-Switching Element And Methods Of Forming The Same” (hereinafter “the '154 Application”), which is hereby incorporated by reference herein in its entirety for all purposes, describes a rewriteable non-volatile memory cell that includes a diode coupled in series with a carbon-based reversible resistivity-switchable material such as carbon.

However, integrating carbon-based resistivity-switchable materials in memory devices is difficult, and improved methods of forming memory devices that employ carbon-based reversible resistivity-switchable materials are desirable.

### SUMMARY

In a first aspect of the invention, a method of forming a memory device including a carbon-based resistivity-switchable material is provided, the method including: (1) introducing a processing gas into a processing chamber, the processing gas including a hydrocarbon compound and a carrier gas; and (2) generating a plasma of the processing gas to deposit a layer of the carbon-based resistivity-switchable material on a substrate within the processing chamber.

In a second aspect of the invention, a microelectronic structure is provided, the microelectronic structure including: (1) a first conductor; (2) a layer of carbon-based resistivity-switchable material disposed above and in series with the first conductor, the carbon-based resistivity-switchable material including graphitic nanocrystallites; and (3) a second conductor disposed above and in series with the layer of carbon-based resistivity-switchable material.

In a third aspect of the invention, a method for forming a microelectronic structure is provided, the method including: (1) forming a first conductor; (2) forming a layer of carbon-based resistivity-switchable material above and in series with the first conductor, the layer carbon-based resistivity-switchable material including graphitic nanocrystallites; and (3) forming a second conductor above and in series with the layer of carbon-based resistivity-switchable material.

Other features and aspects of this invention will become more fully apparent from the following detailed description, the appended claims and the accompanying drawings.

### BRIEF DESCRIPTION OF THE DRAWINGS

Features of the present invention can be more clearly understood from the following detailed description considered in conjunction with the following drawings, in which similar reference numerals denote similar elements throughout, and in which:

FIG. 1 represents a memory cell in accordance with the present invention;

FIG. 2 is a flowchart of an exemplary method in accordance with the present invention;

FIG. 3 is cross-sectional, side elevational representation of an exemplary carbon-based switchable layer formed in accordance with the present invention;

FIG. 4 is a cross-sectional, side elevational view of an exemplary metal-insulator-metal carbon-based structure provided in accordance with the present invention;

FIG. 5 is a cross-sectional, side elevational view of an exemplary carbon-based structure formed by damascene integration in series with a diode and provided in accordance with the present invention; and

FIG. 6 is a perspective view of an exemplary memory level of a monolithic three dimensional memory array provided in accordance with the present invention.

### DETAILED DESCRIPTION

Certain carbon-based (“C-based”) films, including but not limited to carbon nanotubes (“CNTs”), graphene, amorphous carbon containing microcrystalline and/or nanocrystalline graphene, and other graphitic carbon films, etc., may exhibit reversible resistivity switching properties that may be used to form microelectronic non-volatile memories. Such films therefore are candidates for integration within a three-dimensional memory array. For instance, CNT materials have demonstrated memory switching properties on lab-scale devices with a 100× separation between ON and OFF states and mid-to-high range resistance changes. Such a separation between ON and OFF states renders CNT materials viable candidates for memory cells formed using the CNT materials in series with vertical diodes, thin film transistors or other steering elements.

In the aforementioned example, a metal-insulator-metal (“MIM”) stack formed from a carbon-based resistivity-switching material sandwiched between two metal or otherwise conducting layers may serve as a resistance change material for a memory cell. In an MIM memory structure, each “M” represents a metal electrode or other conductive layer, and the “I” represents an insulator-type layer used to store a data state. Moreover, a carbon-based MIM stack may be integrated in series with a diode or transistor to create a read-writeable memory device as described, for example, in the '154 Application.

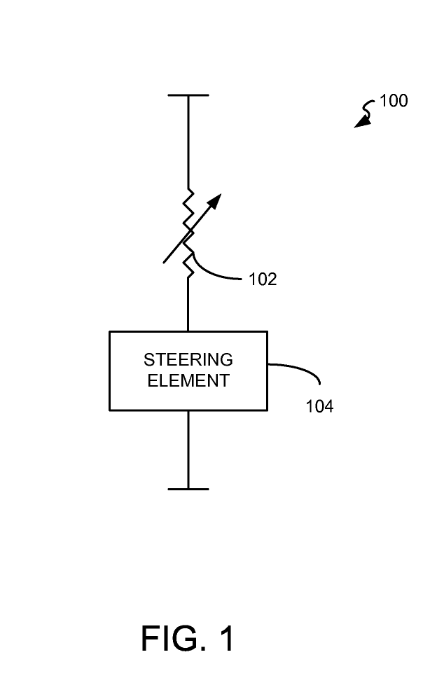

FIG. 1 is a schematic illustration of an exemplary memory cell 100 in accordance with the present invention. The memory cell 100 includes a C-based, reversible resistance-switching element 102 coupled to a steering element 104. For example, a C-based resistivity switching element 102, such as the MIM stack in FIG. 4, may be placed in series with a steering element 104, such as diode 510 in FIG. 5, to form memory cell 100. The steering element 104 may include a thin film transistor (“TFT”), a diode, or another suitable steering element that exhibits non-ohmic conduction by selectively limiting the voltage across and/or the current flow through the reversible resistance-switching element 102.

In accordance with exemplary embodiments of the present invention, methods and apparatus may involve a microelectronic structure, such as a memory device, having a carbon-based resistivity-switching material in an MIM stack. The carbon-based resistivity-switching material may be formed using plasma enhanced chemical vapor deposition (“PECVD”). The carbon layer may be amorphous and comprise carbon-based switchable material. The carbon-based switchable material may comprise nanometer-sized or larger regions of crystalline graphene (referred to herein as “graphitic nanocrystallites”). The MIM may be integrated in series with a steering element, such as a diode, to form a memory cell.

The carbon-based resistivity-switchable material may include carbon in many forms, including CNTs, graphene, graphite, amorphous carbon, graphitic carbon and/or diamond-like carbon. The nature of the carbon-based resistivity-switching material may be characterized by its ratio of forms of carbon-carbon bonding. Carbon typically bonds to carbon to form either an sp²-bond (a trigonal carbon-carbon double bond (“C═C”)) or an sp³-bond (a tetrahedral carbon-carbon single bond (“C—C”)). In each case, a ratio of sp²-bonds to sp³-bonds can be determined via Raman spectroscopy by evaluating the D and G bands. In some embodiments, the range of materials may include those having a ratio such as M_{y}N_{z} where M is the sp³ material and N is the sp² material and y and z are any fractional value from zero to 1 as long as y+z=1. Diamond-like carbon comprises mainly sp³-bonded carbon that forms an amorphous layer.

Aspects of the present invention relate to using PECVD techniques to form amorphous carbon-based resistivity-switching material having graphitic nanocrystallites. PECVD deposition temperatures may range from about 300° C. to 900° C. A processing gas may include one or more precursor gases and one or more dilution gases, also known as carrier gases. A precursor gas source may include, but is not limited to, hexane, cyclo-hexane, acetylene, single and double short chain hydrocarbons (e.g., methane), various benzene based hydrocarbons, polycyclic aromatics, short chain ester, ethers, alcohols, or a combination thereof. In some cases, a “seeding” surface may be used to promote growth at reduced temperatures (e.g., about 1-100 angstroms of iron (“Fe”), nickel (“Ni”), cobalt (“Co”) or the like, although other thicknesses may be used).

The carbon-based resistivity-switchable material may be deposited in any thickness. In some embodiments, the carbon-based resistivity-switchable material may be between about 50-1000 angstroms, although other thicknesses may be used. Depending on device construction, such as described herein, layer thickness ranges may include 100-400 angstroms, 400-600 angstroms, 600-800 angstroms, and 800-1000 angstroms. Persons of ordinary skill in the art will understand that other thickness ranges also may be used.

### Plasma-Enhanced Chemical Vapor Deposition (PECVD)

In one or more embodiments of the invention, a PECVD process is provided that may form graphene, graphitic carbon, CNTs, amorphous carbon with microcrystalline graphene, and other similar carbon-based read-writeable resistivity switching materials (“C-based switchable materials”). As will be described further below, such a PECVD process may provide numerous advantages over conventional thermal CVD processes including, in some embodiments, (1) reduced thermal budget; (2) broad process windows; (3) adjustable programming voltages and currents; and (4) tailored interfaces.

Reduced Thermal Budget

By employing PECVD to form C-based switchable materials, source gases may be dissociated at reduced temperatures, reducing the thermal budget of any memory cell and/or array formed using the C-based switchable materials. In some embodiments, C-based switching materials may be formed at temperatures of about 550° C. or less, allowing copper, aluminum or other similar materials to be employed within a memory array.

Broad Process Windows

Manipulation of plasma processing conditions such as gas flow rates, radio-frequency (“RF”) power, chamber pressure, electrode spacing and/or process temperature during PECVD film deposition may provide a broad window for film property engineering. For example, film density, etch selectivity, stress, conformality/step coverage, percent volume (“vol %”) of nanocrystallinity, graphitic nanocrystallite size, graphitic nanocrystallite orientation and the like may be adjusted based on different etch schemes to be employed during device fabrication.

Adjustable Programming Voltages and Currents

Adjustment of the film properties may modulate the programming voltage and current of a C-based film. For instance, changes in percent volume of nanocrystallinity and/or graphitic nanocrystallite size may change the programming voltage and current. From a parameter perspective, adjustment of the heater temperature, dilution of precursor, high frequency RF power density, ion energy and choice of carrier gas may be employed to control the structure of a C-based film, such as by reducing C-based material deposition rate, promoting dense packing, and/or controlling nanocrystallinity of a C-based film.

Achieving Graphitic Nanocrystallinity

Formation of a graphitic nanocrystalline film may involve an increased heater temperature, an increased high frequency RF power density, control of ion energy within an effective window, and/or an increased dilution of CₓH_{y} precursor. Each of these will be described in turn.

Increasing heater temperature and dilution of precursor reduces deposition rate and thus promotes dense packing and ordering of the structure.

Increasing high frequency RF power density has two major impacts on a plasma process, in which ionization and dissociation may generate both reactive radicals (majority species) and reactive ions (minority species). First, increasing high frequency RF power density will supply more energy to plasma to breakdown precursor molecules into reactive species more effectively, especially at low heater temperature. Second, increasing high frequency RF automatically will increase ion energy and deposition rate. Increasing ion energy will activate surface reactive sites and promote surface reactions that may reduce nanocrystallinity. Therefore, there is an effective high frequency RF power density window, within which reactive species may be broken down more effectively at low heater temperature to increase nanocrystallinity. Conversely, a high frequency RF power density in excess of the effective window will result in amorphorization of nanocrystalline phase carbon.

Similarly to the high frequency RF power density, there is an effective ion energy window as well. On the one hand, a threshold ion energy is required to activate surface sites at a specific heater temperature. On the other hand, excessive ion energy will amorphorize a nanocrystalline carbon film.

The level of dilution of the precursor gas by the carrier gas and the choice of carrier gas also affect the deposition rate and thus nanocrystallinity. For example, as compared to helium (“He”), argon (“Ar”) will increase the deposition rate by almost twice, and thus reduce nanocrystallinity. Conversely, hydrogen (“H₂”) acts not only as a carrier gas, but also serves as etchant, which reduces deposition rate and thus promotes nanocrystallinity.

Modulating ion force and/or reducing radical concentration may decrease the flow of carbon-layer-forming species to a layer surface and allow more time for carbon atoms to reach an equilibrium state. More graphitic nanocrystals thereby may be formed. The sp²/sp³ bonding ratio ionization may decrease graphitic nanocrystallinity and increase the amorphousness of a C-based film (and increase deposition rate dramatically). Furthermore, too much plasma ionization may induce excessive compressive stress in a C-based film and cause film “peeling” or “cracking.”

Dense packing of C-based material may be promoted on a surface by physical bombardment on the substrate surface, which itself may be promoted by mild to moderate plasma ionization. Reactive ions may activate a surface and may modulate the surface reaction rate and surface packing density. Likewise, optimized plasma ion energy may produce a more ordered C-based structure. The concentration of incoming reactive ion species, however, may be determined by the concentration of reactive radicals.

Modulating Graphitic Nanocrystallite Size

As mentioned above, programming voltage and current are affected by graphitic nanocrystallite size, because switching mainly occurs at the grain boundaries. Volume percentage of grain boundary is determined by grain size of graphitic nanocrystallites. Grain size may be controlled by adjusting heater temperature, dilution of CₓH_{y} precursor gas, high frequency RF power density and/or ion energy.

Increasing heater temperature and dilution of CₓH_{y} precursor gas will increase graphitic nanocrystallite size. As with breakdown of reactive species, maintaining the high frequency RF power density within an effective range may achieve the desired graphitic nanocrystallite size. When the high frequency RF power exceeds the effective range, graphitic nanocrystallite size will be reduced. Within the effective ion energy window mentioned above, ion energy preferably is reduced to a minimum level necessary to activate surface reactive sites to allow surface reaction to occur, inasmuch as excessive ion energy will reduce the graphitic nanocrystallinity and graphitic nanocrystallite size.

For example, ion energy may be modulated by adjusting one or more of (a) high frequency RF power (frequency range from 10 MHz to 30 MHz); (b) bias on a substrate (e.g., about 10-50V); (c) low frequency RF (frequency in the range of 10 KHz and about 1 MHz); (d) ionization gas species (such as argon (“Ar”), helium (“He”), hydrogen (“H₂”), xenon (“Xe”), krypton (“Kr”), etc.). He and H₂ are preferred species in this case. Ar, Xe, Kr, etc., are noble gases which are 10 times more massive than He and H₂ and induce more intensive bombardment on a surface with higher momentum. The deposition rate may be approximately doubled by using Ar in place of He or H₂ (with all other process conditions kept constant). Therefore, in some embodiments, He and H₂ are preferred dilution/carrier gas species to keep deposition rate low.

Tailored Interfaces

Adjusting plasma parameters at the beginning and end of C-based layer formation allows interfaces between the C-based switchable layer and other materials such as conductors, dielectrics, etc., to be engineered (e.g., to improve interface adhesion, provide improved sealing or capping properties, reduce film defects, etc.). An engineered C-based layer interface may include (1) an adjusted sp²/sp³ ratio, with increased sp³ concentration for the interface; (2) a higher film density at the interface; and/or (3) a nitridized region at the interface. For instance, the previously incorporated '315 application describes C-based interface layers formed using PECVD.

Exemplary PECVD Chamber

A PECVD chamber may be employed to deposit a C-based switchable material in accordance with the present invention. For example, the PECVD chamber may be based on a PRODUCER™ PECVD chamber available from Applied Materials, Inc., of Santa Clara, Calif., or any other similar PECVD chamber in which the plasma processes of the invention can be performed. An example of such a PECVD process chamber is described in U.S. Pat. No. 5,000,113, titled “Thermal CVD/PECVD Reactor and Use for Thermal Chemical Vapor Deposition of Silicon Dioxide and In-situ Multi-step Planarized Process,” which is incorporated herein by reference in its entirety for all purposes.

The exemplary PECVD system identification is mainly for illustrative purposes, and other plasma equipment, such as electrode cyclotron resonance (“ECR”) plasma CVD devices, induction-coupled RF high density plasma CVD devices, or the like may be employed. Additionally, variations of the abovementioned systems are possible, such as variations in substrate support design, heater design, location of RF power connections, electrode configurations, and other aspects.

### Exemplary PECVD Parameters for C-Based Switching Layers

As discussed above, deposition rate may be controlled to affect nanocrystallinity and graphitic nanocrystallite size in a C-based film. The structure of amorphous carbon films also may be modulated by substrate temperature, precursor-to-dilution gas ratio, high frequency RF power density, carrier gas type, and/or ion energy, which also affect the deposition rate and are dominant factors to produce an ordered structure.

For example, increasing dilution/carrier gas to precursor gas ratio may reduce the concentration of reactive precursor species, may greatly decrease deposition rate, and potentially may provide sufficient time for species on a surface to diffuse to a low energy position and form an ordered structure. Process pressure has a similar effect on deposition rate, within a window of effectiveness. Reducing process pressure may produce similar conditions by reducing the total amount of reactive precursor molecules at a substrate surface, likewise decreasing the deposition rate. Meanwhile, reducing pressure also increases ion energy, and excessive ion energy may amorphorize the nanocrystalline structure. Increasing substrate temperature promotes surface diffusion, which may produce a more densely packed and ordered structure. However, increasing substrate temperature may negatively affect thermal budget. Effect of high frequency RF power density and ion energy have been discussed earlier. There is an effective window for both parameters. If high frequency RF power density and ion energy are too low, deposition will be close to zero. If high frequency RF power density and ion energy are too high, amorphous phase will increase. Different carries gas also greatly affects deposition rate. For instance, Ar produces a higher deposition rate, He produces a moderate deposition rate, and H₂ produces a lower deposition rate. As a result, He and H₂ will increase nanocrystallinity and graphitic nanocrystallite size of the PECVD C-based films.

In some embodiments of the present invention, radical concentration may be reduced by increasing a carrier or dilution gas (e.g., He, H₂, Ar, Kr, Xe, N₂, etc.) to precursor gas (e.g., CₓH_{y}) ratio. Ionization and moderate physical bombardment also may be adjusted by increasing dilution gas to precursor ratio. Increasing dilution gas flow also may increase ionization and surface physical bombardment. Both Helium and Argon are ion forming species. However, the ionization energy of Argon is much lower than that of Helium, and it is much more effective to ionize Ar than He. Furthermore, some gases, such as H₂, can serve as an etchant to further reduce deposition rate and promote nanocrystallization.

Table 1 below describes exemplary broad and narrow value ranges associated with formation of a C-based switching layer by PECVD in accordance with this invention.

TABLE 1
EXEMPLARY PECVD C-BASED FORMATION VALUES

| FORMATION VALUE | BROAD RANGE | NARROW RANGE |
|---|---|---|
| Deposition Rate (Å/sec) | ≦33 | ≦5 |
| Total Film Thickness (Ang) | ≦1000 | ≦500 |
| Crystallinity (vol %) | >5% | >30% |
| Crystallinity Size (nm) | >1 | 2-10 |
| Sheet Resist. (ohm/square) | >1 × 10³ | >1 × 10⁴ |

Persons of ordinary skill in the art will understand that other similar formation values may be achieved.

Table 2 below describes exemplary broad and narrow process windows for forming nanocrystalline graphitic carbon (“GC”) material by PECVD in accordance with this invention. The graphitic nanocrystalline material may be used to form a C-based switching layer.

TABLE 2
EXEMPLARY PECVD PROCESS PARAMETERS FOR GC

| PROCESS PARAMETER | BROAD RANGE | NARROW RANGE |
|---|---|---|
| Precursor Flow Rate (sccm) | 50-5000 | 50-100 |
| Carrier/Precursor Ratio | >1:1 | 5:1 < x < 50:1 |
| Chamber Pressure (Torr) | 0.2-10 | 4-6 |
| 1^{st} RF frequency (Mhz) | 10-50 | 12-17 |
| 2^{nd} RF frequency (Khz) | 90-500 | 90-150 |
| 1^{st} RF power density (W/cm²) | 0.12-2.80 | 0.19-0.50 |
| 2^{nd} RF power density (W/cm²) | 0-2.8 | 0-0.5 |
| Process Temperature (° C.) | 450-650 | 550-650 |
| Heater to Showerhead (Mils) | 300-600 | 325-375 |

In exemplary embodiments of this invention, the precursor hydrocarbon compounds may have the formula CₓH_{y}, with x ranging from about 2 to 4 and y ranging from about 2 5 to 10, and the carrier gas may comprise any suitable inert or non-reactive gas such as one or more of He, Ar, H₂, Kr, Xe, N₂, etc.

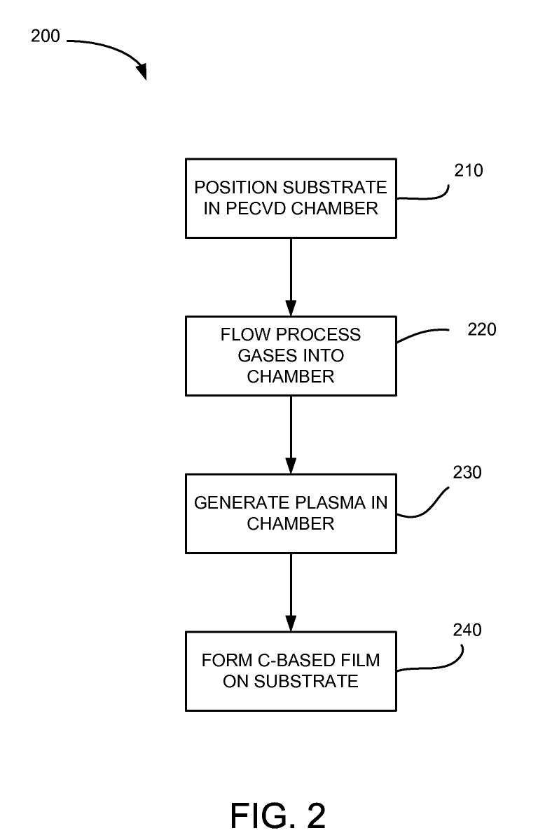

FIG. 2 is a flowchart of an exemplary method 200 for forming a C-based switchable layer in accordance with the present invention. With reference to FIG. 2, in step 210, a substrate is positioned within a PECVD chamber, or any other suitable chamber.

In step 220, a processing gas is introduced into the processing chamber and process gas flow and/or chamber pressure are stabilized. The processing gas may include a precursor gas, such as one or more hydrocarbon compounds, and a carrier/dilutant gas, such as He, Ar, Xe, Kr, H₂, N₂, another inert and/or nonreactive gas, combinations of the same, etc. In some embodiments, the hydrocarbon compounds may include CₓH_{y}, wherein x has a range of about 2 to 4, and y has a range of about 2 to 10. Other hydrocarbon species may be used.

In some embodiments, the processing gas may include a carrier/dilutant gas, such as He, Ar, Kr, Xe, H₂, N₂, another inert and/or nonreactive gas, combinations of the same, etc., and one or more precursor compounds such as C_{A}H_{b}O_{c}NₓF_{y}, wherein “a” has a range from about 1 to about 24, “b” has a range from 0 to about 50, “c” has a range from 0 to about 10, “x” has a range from 0 to about 50, and “y” has a range from about 1 to about 50. Additionally or alternatively, one or more precursor compounds may include, but not limited to, propylene (“C₃H₆”), propyne (“C₃H₄”), propane (“C₃H₈”), butane (“C₄H₁₀”) butylene (“C₄H₈”), butadiene (“C₄H₆”), acetelyne (“C₂H₂”), and combinations thereof.

In some embodiments, achieving one or more of the formation values of Table 1 may involve flowing a precursor gas into the chamber at a rate of about 50 to about 5000 standard cubic centimeters per minute (“sccm”), and more preferably about 50 to about 100 sccm. Carrier/dilutant gas may flow into the chamber at a rate of about 10-20,000 sccm, and more preferably about 1000 to about 5000 sccm. A carrier (dilutant) gas to precursor gas ratio of about 1:1 to about 100:1, and more preferably about 5:1 to about 50:1 may be employed. The chamber pressure may be maintained at about 0.2 to about 10 Torr, more preferably about 4 to about 6 Torr.

In step 230, a plasma of the processing gas is generated by applying power from at least a single frequency RF source. In some embodiments, a twin power source may deliver about 30 to about 1000 Watts (“W”) of first, high frequency RF power to the chamber, with a high frequency RF power more preferably of about 30 to about 250 Watts at a frequency of about 10 to about 50 MHz, and more preferably about 12-17 MHz. A second, low frequency RF power of about 0 to about 500 Watts, and more preferably about 0 to about 100 Watts at about 90 to about 500 KHz, and more preferably about 90 KHz, may be used in some embodiments. An exemplary ratio of second, low frequency RF power to first, high frequency RF power may be about 0 to 0.6. A first power density of about 0.12 to about 2.8 Watts/cm², and more preferably about 0.19 to about 0.5 Watts/cm², may be used. The substrate surface temperature may be maintained at about 450° C. to about 650° C., and more preferably about 550° C. to about 650° C. The electrode spacing of the chamber may be about 300 to about 600 mils, and more preferably about 325 to about 375 mils. Other gas flow rates, gas flow ratios, chamber pressures, RF powers, RF frequencies, RF power ratios, RF power densities, chamber temperatures, electrode spacings and/or parameters may be used.

The process parameters may be adjusted for other chambers, substrate layers, and other gases. In some embodiments, process parameters may be adjusted to improve adhesion, at least at the interface between a C-based switching layer and an adjacent layer (e.g., an adjacent conductive or dielectric layer) without requiring additional deposition of layers. More generally, adjusting plasma parameters at the beginning and end of C-based layer formation allows interfaces between the C-based switchable layer and other materials layers such as conductors, dielectrics, etc., to be engineered (e.g., to improve interface adhesion, provide improved sealing or capping properties, reduce film defects, etc.). An engineered C-based layer interface may include (1) an adjusted sp²/sp³ ratio, with increased sp³ concentration for the interface; (2) a higher film density at the interface; and/or (3) a nitridized region at the interface (e.g., via a plasma process with N₂). Such engineered interfaces are described, for example, in the '315 application.

Returning to FIG. 2, in step 240, a carbon-based resistivity-switching material is formed on the substrate. In some embodiments, a thin passivation layer such as nitridized carbon, silicon nitride, silicon oxynitride or the like may be added to protect the carbon-based resistivity-switching material from further device integration steps. For example, other precursor species such as nitrogen (e.g., N₂), silicon sources, etc., may be provided to the PECVD chamber for passivation layer formation.

In some embodiments, carbon-based resistivity-switching materials may be formed having one or more of the following characteristics or according to one of the following parameters. For example, deposition may occur at a rate of about ≦33 Angstroms/second, and more preferably about ≦5 A/second. Depending on the configuration, amorphous carbon film thickness may vary. For example, in a metal-insulator-metal configuration (see, e.g., FIG. 4), amorphous carbon film thickness may be equal to or less than about 1000 angstroms. For a damascene sidewall integration scheme (see, e.g., FIG. 5), amorphous carbon film thickness may be less than about 100 angstroms, and more preferably less than about 50 angstroms for a memory technology node of 45 nanometers and beyond. Sheet resistivity (“Ω/□”) for a 1000-angstrom film may be from about 1 KΩ/□ to about 10 MΩ/□, and more preferably about 10 KΩ/□. The amorphous carbon film may be formed to have graphitic nanocrystallites. Other films characteristics or formation parameters may be used (e.g., other deposition rates, film thicknesses, sheet resistivities, etc.).

In some embodiments, to improve the integration of a carbon-based resistivity-switching material with an electronic device, such as a nonvolatile memory cell and/or array, the carbon-based film may be conformal with low stress. A high density carbon initiation layer may be used to improve film adhesion. As stated, film density may be increased by lowering deposition rate and modest ionized bombardment to promote dense packing of the film (e.g., via the addition Ar to a He carrier gas and/or addition of low frequency RF power). In some embodiments, a protective conformal passivation SiN layer may be deposited on top of the conformal carbon film. In some embodiments, a conformal top electrode may be formed on top of the conformal carbon film.

By way of example, a C-based switching material memory element formed in accordance with the present invention may be incorporated as part of a two terminal memory cell including a selection device or steering element, e.g., a diode. The C-based switching memory element may include a thin C-based switchable layer (e.g., as thin as a few atomic layers) formed in accordance with the present invention. In another example, a C-based switchable layer formed in accordance with the present invention may be coupled in series with a transistor to form a memory cell.

Memory operation is based on a bi-stable resistance change in the C-based switchable layer with the application of a bias voltage. Current through the memory cell is modulated by the resistance of the C-based switchable layer. In some embodiments, a memory cell is operated by applying a voltage pulse to the memory cell of approximately three volts or more without a current limit to reset the memory cell to a high resistance state. A pulse of approximately three volts or less with a current limit of approximately ten micro amps may set the cell to a low resistance state. The memory cell is read at a lower voltage that will not change the resistance of the C-based switchable layer.

In some embodiments, the difference in resistivities between the two states may be over 100×. The memory cell may be changed from a “0” to a “1,” for example, with the application of high forward bias on the steering element (e.g., a diode). The memory cell may be changed back from a “1” to a “0” with the application of a high forward bias. As stated, this integration scheme can be extended to include C-based switchable materials in series with a TFT or tunnel junction as the steering element instead of a vertical pillar diode. The TFT or tunnel junction steering element may be either planar or vertical. Other memory cell configurations and/or write, read and/or reset conditions may be used.

Electrical tests of exemplary C-based switchable (read-writeable) films formed using one or more of the process parameters of Table 2 have demonstrated both one time programmability and many cycles of reversible, read-writeable characteristics. At least about one order of magnitude difference between the ON/OFF read current at about 0.5V has been observed.

Under certain processing conditions, PECVD formed C-based films, such as amorphous carbon, may contain graphitic nanocrystallites. PECVD process parameters may be used to modulate (a) percentage of a C-based film that is nanocrystalline; (b) size of graphitic nanocrystallites in the C-based film; and/or (c) orientation of graphitic nanocrystallites in the C-based film. In one or more embodiments of the invention, resistivity-switchable amorphous carbon films are provided with graphitic nanocrystalline regions that can be used as a read-writeable memory element.

In one particular embodiment, a C-based switchable material may be formed using C₃H₆ or C₂H₂ at a flow rate of about 20-100 sccm, Helium at a flow rate of about 1000-5000 sccm, an RF power of about 30-250 Watts, a chamber pressure of about 2.5-7 Torr and an electrode spacing of about 200-500 mils. The resultant carbon R/W film produced by the above example would be conductive (ρ=50 KΩ/□ for 1000 Angstroms) and primarily nanocrystalline with graphitic nanocrystallites of about 2-5 nanometers.

Electrical performance of switchable C-based films may be modulated by changing film structure. For example, reducing deposition rate may increase percentage of graphitic nanocrystallites within a C-based film, which may reduce operation current and voltage. The size of the graphitic nanocrystallites also may have a similar effect. In one or more embodiments, graphitic nanocrystallites sized from about 2-10 nanometers may be provided (although other sizes may be provided).

The orientation of the graphitic nanocystallites may affect electrical performance as well. In particular, the orientation of graphitic nanocrystallites may range from completely random to an aligned orientation (or texture). In some embodiments, C-based films formed on different substrates and/or materials may have graphitic nanocrystallites with different orientations. For example, C-based films formed on grown SiOₓ (or another dielectric) may have in some cases, graphitic nanocrystallites that are primarily randomly oriented. Likewise, forming a C-based film on a Si layer may generate a random graphitic nanocrystallite orientation for the read-writeable C-based film. However, C-based films formed on conductive metal layers, such as W or TiN, may have basal planes of grown graphitic nanocrystallites substantially vertically oriented perpendicular to the interface between the conductive layer and C-based film.

Graphitic nanocrystallite orientation also is impacted greatly by process methods. For example, using downstream remote microwave plasma or a completely thermal process, but with zero or minimal in situ RF plasma, may form C-based films having basal planes of grown graphitic nanocrystallites oriented substantially parallel to the growing surface.

As introduced above, a particular advantage of forming such carbon-based resistivity-switching materials by a PECVD process is that PECVD formed C-based switchable materials may be formed at reduced temperatures. In this manner, the thermal budget of a memory element fabrication process may be greatly reduced, allowing use of backend wiring layers such as Cu, Al, and/or other low resistivity materials that are sensitive to higher temperatures, such as those above 600° C. For instance, Al has a melting point of about 660° C. Additionally, temperatures higher than 750° C. may alter dopant profile in a CMOS shallow junction and impact CMOS performance. Temperatures higher than 750° C. for more than 1 minute will also change the dopant profile and junction width in a polysilicon diode used as steering element, which results in an increase of leakage current.

Furthermore, in a three dimensional memory array including stacked levels of memory elements, numerous layers (e.g., 8 layers) of C-based switchable materials may be deposited over one another (e.g., at least one layer of C-based switchable material per level of memory cells). As additional memory levels are added to a three dimensional memory array, previously formed C-based switchable layers are exposed to additional thermal cycles (due to the C-based switchable layer formation process). Use of a low temperature PECVD process to form each C-based switchable layer reduces the affects of such additional thermal cycles, which might otherwise potentially change the structure of previously formed C-based layer films.

Additionally, the thermal expansion coefficient mismatch is high between carbon layers and some metal layers (such as TiN or TaN). As such, a high deposition temperature for a C-based switchable material may produce a high interfacial stress between metal and carbon layers, causing the layers to delaminate from one another. Use of a low temperature PECVD process thus may reduce the interfacial stress between a C-based layer and a metal layer and improve adhesion.

Finally, use of a low process temperature during C-based layer formation may greatly reduce metal electromigration. Such electromigration becomes increasingly important as device geometry is reduced.

The following figures depict further exemplary aspects of the invention. The embodiments shown and described are not intended to limit the invention except as provided by the appended claims. Furthermore, in the embodiments, the order of the layers may be modified and thus, the term “deposited on” and the like in the description and the claims includes a layer deposited above the prior layer but not necessarily immediately adjacent the prior layer and can be higher in the stack.

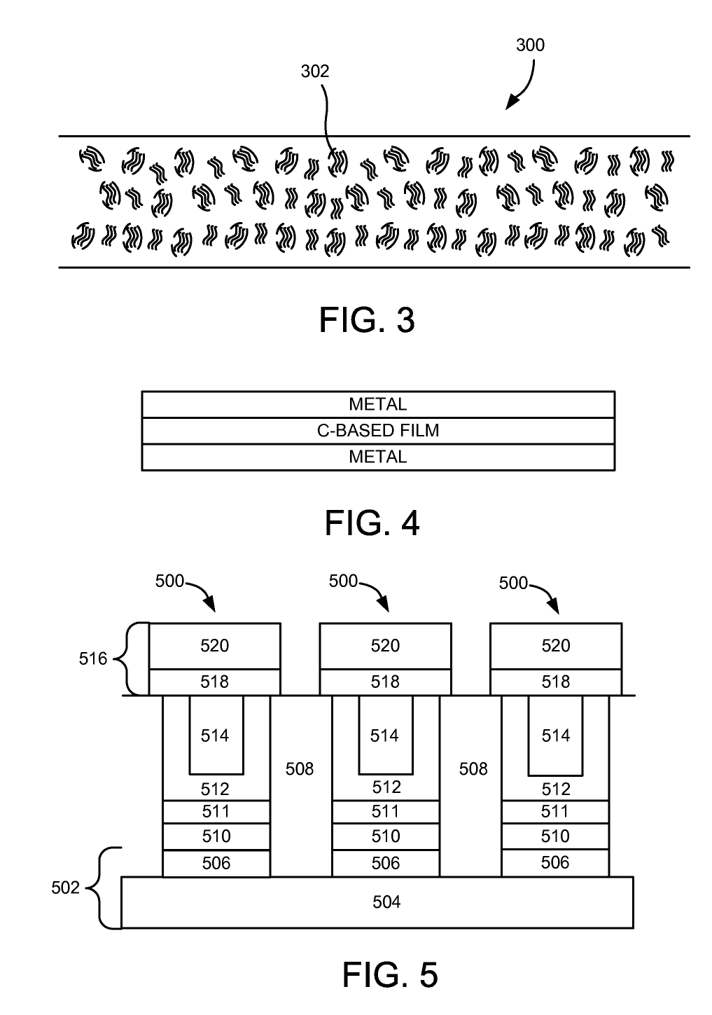

FIG. 3 is a cross-sectional, side elevational representation of an exemplary C-based switchable layer 300 provided in accordance with the present invention. With reference to FIG. 3, a plurality of graphitic nanocrystallites 302 are shown dispersed within the C-based switchable layer 300. Note that the number, size and/or structure of the graphitic nanocrystallites 302 are merely exemplary and are for illustration purposes. Exemplary data indicate that layer 300 includes many graphitic nanocrystallites and few grain boundaries. For instance, a tunneling electron microscope (“TEM”) image of a test structure showed about 90% nanocrystallinity. In this context, the graphitic nanocrystallites 302 comprise regions sp²-bonded graphitic nanocrystalline domains. In contrast, sp³-bonded carbon may include hydrocarbons bonded to each other forming amorphous disordered phases at grain boundaries.

Through use of the previously described PECVD process parameters, the number, size and/or orientation of graphitic nanocrystallites within a C-based layer may be adjusted. For example, in FIG. 3, the graphitic nanocrystallites 302 are primarily vertically oriented, allowing resistivity switching across (vertically in FIG. 3) the C-based layer. Other orientations of the graphitic nanocrystallites 302 may be achieved, such as horizontal and/or random, by manipulation of PECVD process parameters and/or selection of the material on which the C-based layer is formed (as described).

FIG. 4 is a cross-sectional, side elevational view of an exemplary metal-insulator-metal C-based structure provided in accordance with the present invention. The MIM structure includes a C-based film positioned between two or more metal layers (e.g., conductors formed from TiN barrier/adhesion layers and W, for example). Other metal layers may be used. In such an embodiment, electrical current flow through the MIM structure runs perpendicular to the C-based film.

FIG. 5 is a cross-sectional, side elevational view of an exemplary damascene C-based structure having memory cells 500 provided in accordance with the present invention. The damascene structure shown includes three memory cells 500, each of which includes a portion of a bottom conductor 502. Bottom conductor 502 may be formed from a conductive material 504, such as W, and an optional barrier/adhesion material 506, such as TiN, for example. Other conductive materials and barrier/adhesion materials may be used. The barrier/adhesion material 506 may be patterned with the features above it.

A layer of dielectric material 508 may be formed above the bottom conductor 502. Exemplary dielectric materials include SiO₂, SiN, SiON, etc., or other similar dielectric materials. Above the bottom conductor 502 is a diode 510, which may be a p-n, p-i-n, or other similar diode, formed of semiconductor material, such as Si, Ge, SiGe, etc. Above the diode 510 is an optional silicide region 511 formed from semiconductor material from the diode 510. Above the silicide region 511, a conformal C-based film 512 is formed on sidewall regions of a line, trench or via formed in dielectric gap fill material 508. Above the conformal C-based film 512 is depicted a dielectric material 514 that fills in any unoccupied space in the line, trench or via. In some embodiments, dielectric material 514 may include an oxygen-poor material, such as SiN, or other similar dielectric material, and act as a passivation layer. Dielectric material 508 is formed between two or more metal layers (e.g., bottom conductor 502 and top conductor 516, for example). Other metal layers may be used. The line, trench or via may be formed in a dielectric layer such as SiO₂ or another dielectric. Top conductor 516 may be formed above and in contact with the conformal C-based film 512. Like bottom conductor 502, top conductor 516 may include an optional adhesion/barrier material 518 and a conductive material 520. In such an embodiment, electrical current flow through the damascene structure runs substantially parallel to the C-based film (e.g., C-based material on sidewall regions of the line, trench or via). Additional details regarding formation of such a memory cell 500 may be found in the aforementioned '405 application and the '180 application.

In some embodiments, an optional silicide region may be formed in contact with a semiconductor diode, an exemplary embodiment of diode 510. As described in U.S. Pat. No. 7,176,064, which is hereby incorporated by reference herein in its entirety for all purposes, silicide-forming materials, such as titanium and cobalt, react with deposited silicon during annealing to form a silicide layer. The lattice spacings of titanium silicide and cobalt silicide are close to that of silicon, and it appears that such silicide layers may serve as “crystallization templates” or “seeds” for adjacent deposited silicon as the deposited silicon crystallizes (e.g., the silicide layer enhances the crystalline structure of diode during annealing). Lower resistivity silicon thereby is provided. Similar results may be achieved for silicon-germanium alloy and/or germanium diodes. In some embodiments using a silicide region to crystallize the diode, the silicide region may be removed after such crystallization, so that the silicon region does not remain in the finished structure. In some embodiments, a Ti-rich layer may react with an aC switchable layer to form titanium carbide (“TiC”), which may improve adhesion with the aC layer.

As used herein, conformal deposition refers to isotropic, non-directional deposition, wherein a deposited layer conforms to the horizontal as well as vertical topography of an underlying layer. An example of conformal deposition could be deposition of a material on a sidewall of a target layer. Conformal deposition of the amorphous carbon film containing graphitic nanocrystallites is achieved by adjustment of process parameters. For instance, when using C₃H₆ as a precursor, deposition conformality increases as a result of increasing pressure and temperature, reducing He to precursor ratio and reducing power.

By contrast, nonconformal deposition refers to anisotropic, directional deposition, wherein a deposited layer conforms primarily to only the horizontal topography, without depositing much, if any, material on the vertical surfaces, such as sidewalls (e.g., deposition may occur perpendicularly to the target horizontal surface). As an alternative to the conformal deposition of carbon-based film 512 shown in FIG. 5, a non-conformal carbon-based film may be formed. Details of exemplary embodiments of such a non-conformal deposition of a carbon-based film may be found in the aforementioned '180 application.

Moreover, the choice of materials is consistent with the description of the present invention as set forth herein. For instance, conductive material 502 may comprise tungsten (“W”), or another suitable conductive material. In the absence of a diode requiring dopant activation annealing, copper (“Cu”), aluminum (“Al”), and other lower-melting point metals may be used if processing temperatures remain below the corresponding melting point. Analogously, conductive material 520 may comprise tungsten, copper, aluminum, or another suitable conductive material. The bottom barrier layer 506, possibly acting as a lower metal electrode in an MIM structure, may comprise tungsten nitride (“WN”), titanium nitride (“TiN”), molybdenum (“Mo”), tantalum nitride (“TaN”), or tantalum carbon nitride (“TaCN”) or another suitable conductive barrier material. Similarly, the top barrier layer 518, possibly acting as an upper metal electrode in the MIM structure, may comprise similar suitable conductive barrier materials.

Exemplary thicknesses for the bottom and top barrier layers 506, 518 range from about 20 to 3000 angstroms, more preferably about 100 to 1200 angstroms for TiN. The read-writeable material 512 may have a thickness ranging from about 10 to 5000 angstroms, more preferably about 50 to 1000 angstroms for amorphous carbon. The bottom and top conductive materials 504, 520 may range from about 500 to 3000 angstroms, more preferably about 1200-2000 for W. Other materials and/or thicknesses may be used. Exemplary via depths, described below, may range from about 500 to 3000 angstroms (without a diode) and from about 1500 to 4000 angstroms (with a diode). Other via depths may be used.

In accordance with a further exemplary embodiment of this invention, formation of a microelectronic structure includes formation of a monolithic three dimensional memory array including memory cells, each memory cell comprising an MIM device formed by damascene integration, the MIM having a carbon-based resistivity-switching material disposed between a bottom electrode and a top electrode, as described above. The carbon-based resistivity-switching material may comprise an amorphous carbon switchable layer comprising graphitic nanocrystallites.

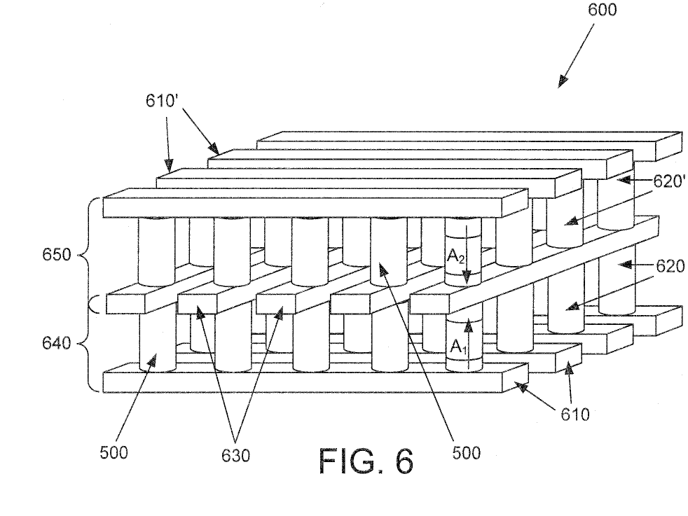

FIG. 6 shows a portion of a memory array 600 of exemplary memory cells formed according to the third exemplary embodiment of the present invention. A first memory level is formed above the substrate, and additional memory levels may be formed above it. Details regarding memory array formation are described in the applications incorporated by reference herein, and such arrays may benefit from use of the methods and structures according to embodiments of the present invention.

As shown in FIG. 6, memory array 600 may include first conductors 610 and 610′ that may serve as wordlines or bitlines, respectively; pillars 620 and 620′ (each pillar 620, 620′ comprising a memory cell 500); and second conductors 630, that may serve as bitlines or wordlines, respectively. First conductors 610, 610′ are depicted as substantially perpendicular to second conductors 630. Memory array 600 may include one or more memory levels. A first memory level 640 may include the combination of first conductors 610, pillars 620 and second conductors 630, whereas a second memory level 650 may include second conductors 630, pillars 620′ and first conductors 610′. Fabrication of such a memory level is described in detail in the applications incorporated by reference herein.

Embodiments of the present invention are useful in formation of a monolithic three dimensional memory array. A monolithic three dimensional memory array is one in which multiple memory levels are formed above a single substrate, such as a wafer, with no intervening substrates. The layers forming one memory level are deposited or grown directly over the layers of an existing level or levels. In contrast, stacked memories have been constructed by forming memory levels on separate substrates and adhering the memory levels atop each other, as in Leedy, U.S. Pat. No. 5,915,167. The substrates may be thinned or removed from the memory levels before bonding, but as the memory levels are initially formed over separate substrates, such memories are not true monolithic three dimensional memory arrays.

A related memory is described in Herner et al., U.S. patent application Ser. No. 10/955,549, “Nonvolatile Memory Cell Without A Dielectric Antifuse Having High- And Low-Impedance States,” filed Sep. 29, 2004 (hereinafter the '549 application), which is hereby incorporated by reference herein in its entirety for all purposes. The '549 application describes a monolithic three dimensional memory array including vertically oriented p-i-n diodes, a semiconductor embodiment of diode 510 of FIG. 5. As formed, the polysilicon of the p-i-n diode of the '549 application is in a high-resistance state. Application of a programming voltage permanently changes the nature of the polysilicon, rendering it low-resistance. It is believed the change is caused by an increase in the degree of order in the polysilicon, as described more fully in Herner et al., U.S. patent application Ser. No. 11/148,530, “Nonvolatile Memory Cell Operating By Increasing Order In Polycrystalline Semiconductor Material,” filed Jun. 8, 2005 (the “'530 application”), which is incorporated by reference herein in its entirety for all purposes.

Another related memory is described in Herner et al., U.S. Pat. No. 7,285,464, (the “'464 patent”), which is incorporated by reference herein in its entirety. As described in the '464 patent, it may be advantageous to reduce the height of the p-i-n diode. A shorter diode requires a lower programming voltage and decreases the aspect ratio of the gaps between adjacent diodes. Very high-aspect ratio gaps are difficult to fill without voids. A thickness of at least 600 angstroms is preferred for the intrinsic region to reduce current leakage in reverse bias of the diode. Forming a diode having a silicon-poor intrinsic layer above a heavily n-doped layer, the two separated by a thin intrinsic capping layer of silicon-germanium, will allow for sharper transitions in the dopant profile, and thus reduce overall diode height.

In particular, detailed information regarding fabrication of a similar memory level is provided in the '549 application and the '464 patent, previously incorporated. More information on fabrication of related memories is provided in Herner et al., U.S. Pat. No. 6,952,030, “A High-Density Three-Dimensional Memory Cell,” owned by the assignee of the present invention and hereby incorporated by reference herein in its entirety for all purposes. To avoid obscuring the present invention, this detail will be not be reiterated in this description, but no teaching of these or other incorporated patents or applications is intended to be excluded. It will be understood that the above examples are non-limiting, and that the details provided herein can be modified, omitted, or augmented while the results fall within the scope of the invention.

The foregoing description discloses exemplary embodiments of the invention. Modifications of the above disclosed apparatus and methods that fall within the scope of the invention will be readily apparent to those of ordinary skill in the art. Accordingly, although the present invention has been disclosed in connection with exemplary embodiments, it should be understood that other embodiments may fall within the spirit and scope of the invention, as defined by the following claims.

1. A method for forming a memory device, the method comprising:
introducing a processing gas into a processing chamber, wherein the processing gas comprises a hydrocarbon compound and a carrier gas; and
generating a plasma of the processing gas to deposit a layer of a carbon-based resistivity-switching material on a substrate in the processing chamber.

2. The method of claim 1, wherein the layer of carbon-based resistivity-switching material comprises graphitic crystallites.

3. The method of claim 2, wherein the graphitic crystallites comprise graphitic nanocrystallites.

4. The method of claim 2, further comprising controlling a size of the graphitic crystallites.

5. The method of claim 4, wherein controlling the size of the graphitic crystallites comprises controlling a deposition rate of the carbon-based resistivity-switching material.

6. The method of claim 4, wherein controlling the size of the graphitic crystallites comprises controlling any of a temperature of the substrate, an ion energy of the plasma, a high frequency RF power density used to generate the plasma, a choice of the carrier gas, and a dilution of the hydrocarbon.

7. The method of claim 2, further comprising controlling a percent volume of the graphitic crystallites.

8. The method of claim 7, wherein controlling the percent volume of the graphitic crystallites comprises controlling a deposition rate of the carbon-based resistivity-switching material.

9. The method of claim 7, wherein controlling the percent volume of the graphitic crystallites comprises controlling any of a temperature of the substrate, an ion energy of the plasma, a high frequency RF power density used to generate the plasma, a choice of the carrier gas, and a dilution of the hydrocarbon.

10. The method of claim 2, wherein the graphitic crystallites have an orientation with basal planes substantially parallel to a surface on which the layer of carbon-based resistivity-switching material is deposited.

11. The method of claim 2, further comprising controlling an orientation of the graphitic crystallites.

12. The method of claim 11, wherein controlling the orientation of the graphitic crystallites comprises depositing the layer of carbon-based resistivity-switching material on a silicon-based material.

13. The method of claim 1, further comprising forming a passivation layer over the carbon-based switchable material.

14. The method of claim 1, wherein the hydrocarbon compound comprises CₓH_{y}, wherein x has a range of 2 to 4 and y has a range of 2 to 10.

15. The method of claim 1, wherein the processing gas comprises hydrogen and a precursor compound having a formula of C_{A}H_{b}O_{c}NₓF_{y}, wherein “a” has a range of between 1 and 24, “b” has a range of between 0 and 50, “c” has a range of 0 to 10, “x” has a range of 0 to 50, and “y” has a range of 1 to 50.

16. The method of claim 1, wherein the hydrocarbon compound comprises any of propylene (C₃H₆), propyne (C₃H₄), propane (C₃H₈), butane (C₄H₁₀), butylene (C₄H₈), butadiene (C₄H₆), acetelyne (C₂H₂), or combinations thereof.

17. The method of claim 1, wherein generating a plasma comprises applying a first RF power at a first frequency and applying a second RF power at a second frequency less than the first frequency.

18. The method of claim 17, wherein the first frequency is between about 10 MHz and about 50 MHz and the second frequency is between about 90 kHz and about 500 KHz.

19. The method of claim 17, wherein the first RF power ranges from about 30 W to about 1000 W, and the second RF power ranges from about 0 W to about 500 W.

20. The method of claim 17, wherein an RF power density of the plasma ranges from about 0 Watt/cm² to about 2.8 Watts/cm².

21. The method of claim 1, wherein the carrier gas comprises at least one of He, Ar, Kr, Xe, H₂ and N₂.

22. The method of claim 1, wherein a ratio of carrier gas to hydrocarbon compounds ranges from about 1:1 to about 100:1.

23. The method of claim 22, wherein the ratio of carrier gas to hydrocarbon compounds is about 5:1 to about 50:1.

24. The method of claim 1, further comprising establishing a pressure in the processing chamber from about 0.2 Torr to about 10 Torr.

25. The method of claim 1, further comprising establishing a pressure in the processing chamber from about 4 Torr to about 6 Torr.

26. The method of claim 1, further comprising providing a hydrocarbon gas flow rate from about 50 standard cubic centimeters per minute to about 5000 standard cubic centimeters per minute.

27. The method of claim 1, further comprising providing a carrier gas flow rate from about 10 standard cubic centimeters per minute to about 20,000 standard cubic centimeters per minute.

28. The method of claim 1, wherein the method comprises a plasma enhanced chemical vapor deposition process.

29. The method of claim 1, further comprising heating the substrate to a surface temperature of between about 450° C. and about 650° C.

30. The method of claim 1, further comprising:
forming a bottom electrode below and in contact with the layer of carbon-based resistivity-switching material; and
forming a top electrode above and in contact with the layer of carbon-based resistivity-switching material;
wherein the bottom electrode, the layer of carbon-based resistivity-switching material, and the top electrode comprise a metal-insulator-metal structure.

31. The method of claim 30, further comprising forming a steering element in series with the layer of carbon-based resistivity-switching material.

32. The method of claim 31, wherein the steering element comprises a diode in vertical alignment with the layer of carbon-based resistivity-switching material.

33. The method of claim 31, further comprising:
forming a first conductor in series with the bottom electrode; and
forming a second conductor above the first conductor, the steering element, and the layer of carbon-based resistivity-switching material, the second conductor being in series with the top electrode;
wherein the first conductor, the steering element, the layer of carbon-based resistivity-switching material, and the second conductor form a microelectronic structure comprising a memory cell.

34. A microelectronic structure comprising:
a first conductor;
a layer of a carbon-based resistivity-switchable material disposed above and in series with the first conductor, wherein the carbon-based resistivity-switchable material comprises graphitic nanocrystallites; and
a second conductor disposed above and in series with the layer of carbon-based resistivity-switchable material.

35. The microelectronic structure of claim 34, wherein the layer of carbon-based resistivity-switchable material comprises a portion of a metal-insulator-metal structure.

36. The microelectronic structure of claim 34, further comprising a steering element disposed above the first conductor, below the second conductor, and in series with the layer of carbon-based resistivity-switching material.

37. The microelectronic structure of claim 36, wherein the steering element comprises a diode.

38. The microelectronic structure of claim 36, wherein the first conductor, second conductor, the steering element, and the layer of carbon-based resistivity-switching material comprise a memory cell.

39. A method for forming a microelectronic structure, the method comprising:
forming a first conductor;
forming a layer of carbon-based resistivity-switchable material above and in series with the first conductor, wherein the layer carbon-based resistivity-switchable material comprises graphitic nanocrystallites; and
forming a second conductor above and in series with the layer of carbon-based resistivity-switchable material.

40. The method of claim 39, wherein the layer of carbon-based resistivity-switchable material comprises a portion of a metal-insulator-metal structure.

41. The method of claim 39, further comprising forming a steering element above the first conductor, below the second conductor, and in series with the layer of carbon-based resistivity-switchable material.

42. The method of claim 41, wherein the steering element comprises a diode.

43. The method of claim 41, wherein the first conductor, second conductor, the steering element, and the layer of carbon-based resistivity-switchable material comprise a memory cell.

44. The method of claim 39, wherein forming the layer of carbon-based resistivity-switchable material comprises plasma enhanced chemical vapor deposition of carbon-based resistivity-switching material.

45. The method of claim 39, further comprising controlling a size of the graphitic nanocrystallites.

46. The method of claim 39, further comprising controlling a percent volume of the graphitic nanocrystallites.

47. The method of claim 39, further comprising controlling an orientation of the graphitic nanocrystallites.
